(19) United States
(12) Patent Application Publication
(10) Pub. No.: US 2025/0085321 A1
(43) Pub. Date: Mar. 13, 2025

(54) CIRCUIT FOR MEASURING A COMPLEX ALTERNATING CURRENT RESISTANCE

(71) Applicant: EBE Elektro-Bau-Elemente GmbH, Leinfelden-Echterdingen (DE)

(72) Inventor: Dirk OLDENDORF, Alling (DE)

(21) Appl. No.: 18/954,840

(22) Filed: Nov. 21, 2024

Related U.S. Application Data
(63) Continuation of application No. PCT/EP2023/064093, filed on May 25, 2023.

(30) Foreign Application Priority Data
Jun. 10, 2022 (DE) 10 2022 114 629.4

(51) Int. Cl. G01R 27/14; G01D 5/24; G01F 23/263

(52) U.S. Cl. CPC G01R 27/14; G01D 5/24; G01F 23/263

(57) ABSTRACT

A circuit for measuring a complex alternating current resistance comprises a signal source which is designed to generate an alternating voltage excitation signal, a first signal path, a second signal path and a third signal path, into each of which the alternating voltage excitation signal of the signal source is fed in parallel to one another. The alternating voltage excitation signal is fed into the first signal path or into the second and third signal path at least temporarily with a phase offset compared to the alternating voltage excitation signal generated by the signal source. The first signal path has a high-pass filter and, in series therewith, the alternating current resistance to be measured. A measurement signal tapped at a measuring point between the high-pass filter and the alternating current resistance to be measured is mixed with the alternating voltage excitation signal in the second signal path and furthermore demodulated in order to obtain a first demodulated measurement signal. The measurement signal tapped at the measuring point is also mixed with the alternating voltage excitation signal in the third signal path and furthermore demodulated in order to obtain a second demodulated measurement signal. A signal evaluation unit, which receives the demodulated measurement signals, determines from the demodulated measurement signals the imaginary part and real part of the alternating current resistance to be measured.

### CROSS-REFERENCE TO RELATED APPLICATIONS

This application is a continuation of international patent application PCT/EP2023/064093 filed on May 25, 2023 designating the U.S., which international patent application claims priority from German patent application 10 2022 114 629.4 filed on Jun. 10, 2022. The entire contents of these priority applications are incorporated herein by reference.

### BACKGROUND

The invention relates to a circuit for measuring a complex alternating current resistance.

Such a circuit can be used for an impedance sensor in various applications.

Document EP 3 512 099 B1 discloses a capacitive sensor having a sensor electrode, wherein the sensor electrode is connected to a signal generation circuit for generating an output signal to the sensor electrode, and wherein the sensor electrode is further connected to a signal evaluation circuit configured to evaluate an input signal from the sensor electrode. The signal evaluation circuit has a synchronous rectifier, wherein the synchronous rectifier comprises a first and a second switch which are connected to the signal generator and are configured for alternating switching in phase with the input signal. With this known sensor, only the imaginary part of a complex alternating current resistance can be measured.

Further capacitive sensors are known from US 2015/0323372 A1 and DE 10 2012 201 226 B4. The latter document discloses a probe for a capacitive level sensor with a measuring impedance, a reference impedance, a first rectifier and a second rectifier, two measuring resistors, a ground connection and a connection configured for connecting a multi-core connecting line, wherein the connecting line has a first core for transmitting a transmission signal and four further cores for transmitting DC voltage signals. This circuit is comparatively complex.

DE 10 2018 209 904 A1 discloses a fill level sensor or limit level sensor with temperature compensation. The sensor has a processing unit for processing a measurement signal generated by means of the sensor, and a reference unit for generating a reference signal, wherein the processing unit and the reference unit each have a signal converting unit with temperature-dependent signal conversion.

### SUMMARY

The invention is based on the object of providing a circuit for measuring an unknown complex alternating current resistance, which is simply constructed and with which it is possible, in particular, to measure the imaginary part and real part of an alternating current resistance.

According to an aspect, a circuit for measuring a complex alternating current resistance is provided, comprising a signal source that is designed to generate an alternating voltage excitation signal, a first signal path, a second signal path and a third signal path. The alternating voltage excitation signal of the signal source is fed into each of the first signal path, the second signal path and the third signal path in parallel to one another. The alternating voltage excitation signal is fed into the first signal path or into the second and third signal path at least temporarily with a phase offset compared to the alternating voltage excitation signal generated by the signal source. The first signal path comprises a high-pass filter and, in series therewith, the alternating current resistance to be measured. A measurement signal tapped at a measuring point between the high-pass filter and the alternating current resistance to be measured is mixed with the alternating voltage excitation signal in the second signal path and furthermore demodulated in order to obtain a first demodulated measurement signal, and is mixed with the alternating voltage excitation signal in the third signal path and furthermore demodulated in order to obtain a second demodulated measurement signal. The circuit further comprises a signal evaluation unit that receives the demodulated measurement signals and determines from the demodulated measurement signals the imaginary part and real part of the alternating current resistance to be measured.

The circuit according to the invention can be used to measure an unknown alternating current resistance which is, for example, connected to a measuring electrode against a reference potential, wherein the reference potential can be the reference potential of the signal source. The circuit has a signal source which generates an alternating voltage excitation signal, wherein the spectrum of the signal source is preferably selected such that a broad frequency spectrum or signal band is utilized. The alternating voltage excitation signal is fed into a first signal path, which has a high-pass filter and, in series therewith, the alternating current resistance to be measured. The high-pass filter and the alternating current resistance to be measured form an alternating-voltage divider. The alternating voltage excitation signal is fed into a second signal path and a third signal path at the same time as being fed into the first signal path. The measurement signal, which is used to measure the complex alternating current resistance, is tapped between the high-pass filter and the alternating current resistance to be measured. The circuit according to the invention further provides for setting a phase offset at least temporarily. When the phase offset is switched on, an alternating voltage excitation signal that is phase-rotated compared to the alternating voltage excitation signal generated by the signal source is fed into the first signal path or into the second and third signal path. The alternating current resistance can be measured alternately with the phase offset switched on and off. The phase offset can be, for example, 0° (off), 90°, 180°, or 270°, which also includes −90°, −180°, or −270°. The measurement signal tapped at the measuring point between the high-pass filter and the alternating current resistance to be measured is mixed with the alternating voltage excitation signal in the second signal path and third signal path. When phase offset is switched on, the phase-shifted measurement signal is mixed with the non-phase-shifted alternating voltage excitation signal and demodulated, or the non-phase-shifted measurement signal is mixed with the phase-shifted alternating voltage excitation signal, depending on whether phase offset is present in the first signal path or in the second and third signal path. Phase offset can be achieved by a phase shifter. Mixing and demodulating is comparable to amplitude demodulation. The signal evaluation unit receives the demodulated measurement signals, which may have been low-pass filtered, and on the basis of these signals determines the imaginary part and real part of the alternating current resistance to be measured, which is made possible by the temporarily switched-on phase offset which allows not only for amplitude determination, but also for phase determination of the alternating current resistance.

The circuit according to the invention is simply constructed and thus allows for a simple measuring of the reactive component and active component of a complex alternating current resistance.

Preferred embodiments are specified in the dependent claims or are described below.

In a preferred embodiment, the second signal path may comprise a first diode and a first measuring capacitor, wherein the measuring capacitor is connected to the measuring point between the high-pass filter and the alternating current resistance to be measured, and the third signal path may comprise a second diode and a second measuring capacitor, wherein the second measuring capacitor is connected to the measuring point between the high-pass filter and the alternating current resistance to be measured, wherein the first and the second diode are arranged to alternately pass a half-wave of the alternating voltage excitation signal.

The two measuring capacitors together with the two diodes form a simple arrangement for mixing the measurement signal tapped at the measuring point with the respective alternating voltage excitation signal guided in the second and third signal path, and for demodulating the signals thus mixed. The diodes are connected via the measuring capacitors to the measuring point between the high-pass filter and the complex alternating current resistance. The circuit is configured such that during the positive half-wave of the alternating voltage excitation signal of the signal source, one diode is conductive and a current flows through the associated measuring capacitor, whereby the current through the measuring capacitor charges the latter to a measuring voltage proportional to the alternating voltage divider. During the negative half-wave of the alternating voltage excitation signal of the signal source, the other diode is conductive, so that a charging current flows through the associated measuring capacitor. The measurement signal at the measuring point is separated from the DC component of the alternating voltage excitation signal via the high-pass filter and the two measuring capacitors.

Preferably, the first measuring capacitor and/or the second measuring capacitor have a capacitance in the picofarad range.

Furthermore, an inverter may be arranged in the second or in the third signal path, which inverter is connected to the signal source and is connected upstream of the first diode or the second diode and inverts, i.e. rotates, the alternating voltage excitation signal coming from the signal source by 180°.

In this embodiment, the two diodes can be arranged with the same polarity in the second and third signal path. However, it is also possible to connect the two diodes with opposite polarity to the signal source and, optionally, couple in a bias voltage so that an inverter is not required.

Furthermore, the high-pass filter may comprise a capacitor, in particular only one capacitor.

This further simplifies the circuit in terms of its complexity. The capacitance of the capacitor of the high-pass filter may be selected as a function of the expected value range of the alternating current resistance to be measured. It is preferred if the largest possible voltage swing is achieved between the measurement signal level at low measuring impedance and high measuring impedance.

It is understood that additional filter and protection elements can be arranged between the high-pass filter and the measuring electrode to which the complex alternating current resistance is connected in order to optimize the EMC properties of the circuit.

The frequency spectrum of the alternating voltage excitation signal that can be generated by the signal source preferably comprises frequencies in a broad frequency band. Preferably, the frequencies that can be generated are in a range of 100 kHz to 200 MHz, depending on the signal source used. The circuit may, for example, be operated at frequencies between 5 and 50 MHz. A voltage-controlled oscillator (VCO) controlled by a microcontroller may be used as a signal source, wherein the control voltage depends on the input range of the voltage-controlled oscillator and serves to generate a broadband output spectrum at the output of the voltage-controlled oscillator. Alternatively, instead of a voltage-controlled oscillator, an oscillating signal source contained in a microcontroller can be modulated accordingly to output a broadband frequency spectrum.

Preferably, the signal source is configured to generate the alternating voltage excitation signal with time-varying frequency. For this purpose, the signal source may be configured, for example, in the form of a sweep generator. This makes it easy to improve the EMC properties of the circuit.

Further preferably, the circuit may comprise a first low-pass filter and a second low-pass filter into which the demodulated measurement signals are fed. The low-pass filter can be used to separate the alternating voltage signal component from the demodulated measurement signals. An analog-to-digital converter (ADC) may be arranged downstream of the low-pass filters which digitizes the measurement signals. It is also possible to use only one ADC, wherein the optional subtraction stage mentioned above is performed via an analog stage before digitization.

The signal evaluation unit may preferably be designed to subtract the demodulated measurement signals from one another. The advantage here is that, on the one hand, the measurement signal is increased and, on the other hand, external interference signals are eliminated. The complex alternating current resistance can then be determined based on the difference between the measurement signals.

Furthermore, according to the invention, an impedance sensor is provided which comprises a measuring electrode to which the complex alternating current resistance to be measured is connected against a reference potential and comprises a circuit according to one or more of the embodiments mentioned above.

The impedance sensor according to the invention can be used in a variety of applications. In particular, the impedance sensor is capable of detecting not only the capacitance between the measuring electrode and the reference potential, specifically ground potential, but also the conductive coupling between the measuring electrode and the reference potential, which is determined by the real part of the complex alternating current resistance. This makes it possible, for example, to differentiate objects or detect contamination.

For example, the impedance sensor can be used as a fill level sensor to continuously monitor, for example, liquid media or bulk materials in a tank. The measuring electrode can be designed as a rod. A conductive sheath tube or the conductive wall of the tank can serve as a counter electrode. The measuring electrode and the counter electrode form a capacitor. The value of the capacitor is continuously changed by the fill level in the tank and can be measured by the circuit according to the invention. Conductive contamination, such as biofilms or other deposits in the tank, can be detected via the conductive measurement value (conductance) of the circuit according to the invention. However, changes in the media properties, which are reflected in the conductivity of the process medium, can also be detected via the conductive measurement value.

The impedance sensor can also be used as a limit level switch for a process medium. The measuring electrode can be designed as a cap, for example. If the cap of the limit level switch is contacted by the process medium, the measured capacitance changes significantly and switching activity can be triggered. This makes it possible, for example, to implement dry-run protection for pumps or overflow protection when filling open containers. Here, too, the conductive measurement value can be used to detect contamination or changes in the process medium.

Furthermore, the impedance sensor can be used as a proximity sensor, e.g., in the automation industry. A switching activity can be triggered similarly to a limit level switch. For example, as soon as an object comes closer to the measuring electrode, the capacitance between the measuring electrode and the reference potential, e.g., the ground potential, changes. A switching activity can be triggered if the signal change due to this capacitance is sufficiently large. The conductive measurement can be used to distinguish objects. However, it can also be used to detect conductive deposits on the measuring electrode of the proximity sensor. This makes it possible to continue to detect objects in processes in which, for example, water films or puddles form on the proximity sensor.

Further possible uses of the impedance sensor according to the invention are in the field of man-machine interaction in the form of buttons, slide or rotary encoders. The impedance sensor according to the invention can moreover be used as a flow monitor in which the properties of the process medium are monitored in relation to capacitive or conductive coupling to the sensor.

Further advantages and features become apparent from the following description and the attached drawings.

It should be appreciated that the features mentioned above and those to be explained below can be used not only in the combination specified in each case, but also in other combinations or on their own without departing from the scope of the present invention.

### BRIEF DESCRIPTION OF THE DRAWINGS

Exemplary embodiments of the invention are shown in the drawing and are described in more detail below with reference thereto. In the drawings:

FIG. 1 shows a principle circuit diagram of an alternating voltage divider with an alternating current resistor;

FIG. 2 shows a circuit diagram of a first exemplary embodiment of a circuit for measuring a complex alternating current resistance;

FIG. 3 shows another circuit diagram of a further exemplary embodiment of a circuit for measuring a complex alternating current resistance;

FIG. 4 shows another circuit diagram of a further exemplary embodiment of a circuit for measuring a complex alternating current resistance;

FIG. 5 shows another circuit diagram of a further exemplary embodiment of a circuit for measuring a complex alternating current resistance;

FIG. 6 shows another circuit diagram of a further exemplary embodiment of a circuit for measuring a complex alternating current resistance;

FIG. 7 shows another circuit diagram of a further exemplary embodiment of a circuit for measuring a complex alternating current resistance;

FIG. 8 shows another circuit diagram of a further exemplary embodiment of a circuit for measuring a complex alternating current resistance; and

FIG. 9 shows a schematic sketch of a possible use of an impedance sensor.

### DETAILED DESCRIPTION OF EXEMPLARY EMBODIMENTS

FIG. 1 shows a principle of a circuit diagram of an alternating voltage divider with an unknown, in particular variable, alternating current resistance Z, which is provided with reference number 1 in FIG. 1. The unknown alternating current resistance Z is connected to a measuring electrode 2 against a reference potential 3. To measure the unknown alternating current resistance Z, the measuring electrode 2 is connected to a signal source 4 via an internal coupling capacitor CK, as shown with reference number 5 in FIG. 1. The reference potential 3 can be the reference potential of the signal source 4. The coupling capacitor CK together with the unknown alternating current resistance Z forms an alternating voltage divider for the voltage of the signal source 4. The spectrum of signal source 4 should ideally be selected such that a broad signal band is utilized. On the one hand, this serves to distribute the output power over many frequencies, and on the other hand, it reduces the sensitivity of the measurement to external signal sources. The measuring voltage V of the alternating voltage divider built from the coupling capacitor CK and the alternating current resistance Z to be determined is tapped at a measuring point between the coupling capacitor CK and the alternating current resistance Z. In FIG. 1, the measuring voltage V is tapped directly at the measuring electrode 2 in parallel to the alternating current resistance Z.

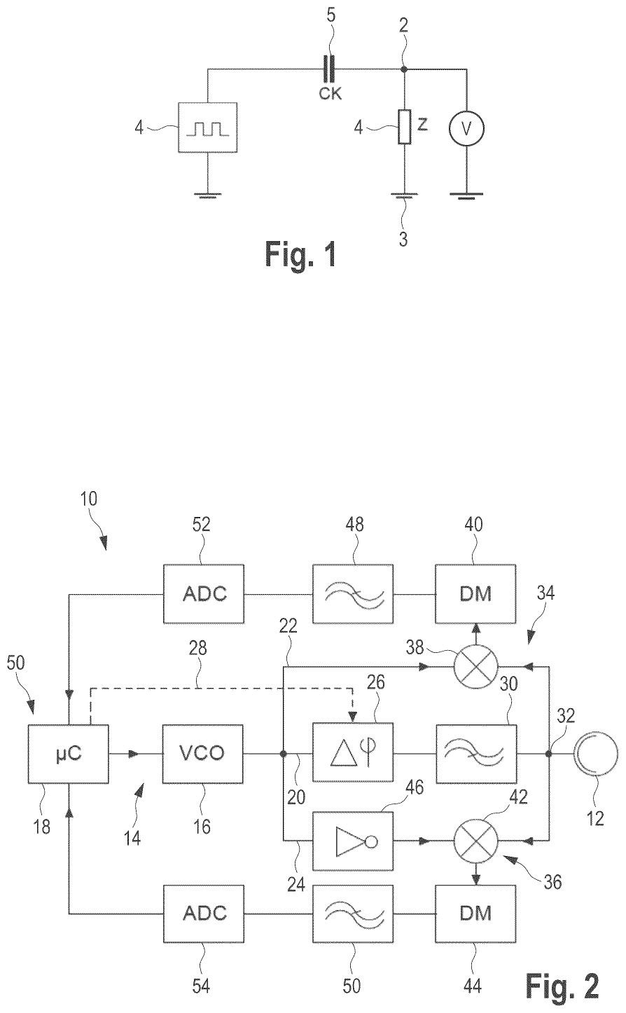

With reference to FIGS. 2 to 4, exemplary embodiments of circuits are described below with which the complex alternating current resistance Z can be measured in a simple manner.

FIG. 2 shows a circuit 10 for measuring a complex alternating current resistance connected to a measuring electrode 12 against a reference potential, as described with reference to FIG. 1. The alternating current resistance Z is not shown in FIG. 2.

The circuit 10 comprises a signal source 14 which is designed to generate an alternating voltage excitation signal. In the exemplary embodiment in FIG. 2, the signal source 14 has a voltage-controlled oscillator (VCO) 16. A microcontroller (C) 18 generates a control voltage for the voltage-controlled oscillator 16. The control voltage depends on the input range of the voltage-controlled oscillator and serves to generate a broadband output spectrum at the output of the voltage-controlled oscillator 16. The control voltage can be output via a digital-to-analog converter integrated in the microcontroller 18. Alternatively, it is also possible to generate a pulse width modulation (PWM) signal with the microcontroller 18 and to convert said signal—e.g., with the aid of a low-pass filter—into a low-frequency control voltage for the voltage-controlled oscillator. The control signal for the voltage-controlled oscillator can be varied during a sweep time. The temporal progression of the control voltage can be selected such that the frequency spectrum generated by the voltage-controlled oscillator has optimal EMC properties. The sweep time can, for example, range from a few milliseconds to several seconds.

The frequency spectrum of the alternating voltage excitation signal output by the voltage-controlled oscillator 16 can be in the range from a few kHz to several MHz. For example, the frequency spectrum can start at 70 MHz and extend up to a frequency of 150 MHz. The broadband alternating voltage signal spectrum serves to improve the EMC properties of the entire circuit 10. On the one hand, the radiated energy is distributed over many frequencies, and on the other hand, the sensitivity to interference from external signal frequencies is reduced.

Starting from the signal source 14, the circuit 10 comprises a first signal path 20, a second signal path 22 and a third signal path 24, into each of which the alternating voltage excitation signal output by the signal source 14 is fed in parallel to one another.

The alternating voltage excitation signal is fed into the first signal path at least temporarily with a phase offset. For this purpose, a phase shifter 26 (Δφ) is arranged in the first signal path 20. The phase shifter 26 ensures a phase offset of its output signal compared to the alternating voltage excitation signal fed in from the signal source 14. The phase shifter 26 can be controlled by the microcontroller 18, as indicated by a discontinuous line 28. The microcontroller 18 can specify how large the phase offset should be between the input signal fed into the signal path 20 and the output signal at the output of the phase shifter 26. Typically, the phase offset is set to 0°, 90°, 180°, or 270°. However, other phase offsets can also be applied.

The output signal of the phase shifter 26 is coupled into a high-pass filter 30. As shown in exemplary embodiments to be described later, the high-pass filter 30 can be designed as a capacitor, corresponding to the coupling capacitor 5 in FIG. 1. The high-pass filter 30 together with the complex alternating current resistance to be measured externally and connected to the measuring electrode 12 forms an alternating voltage divider, as described above with reference to FIG. 1. At a measuring point 32, which can be located directly on the measuring electrode 12 as described with reference to FIG. 1, the measuring voltage, from which the complex alternating current resistance is determined as described below, is tapped relative to the reference potential, for example the reference potential of the signal source 14.

If the high-pass filter 30 is designed as a capacitor, the capacitance of the capacitor of the high-pass filter 30 is selected as a function of the expected value range of the complex alternating current resistance to be measured. The aim is to achieve the largest possible voltage swing between the alternating voltage level of the measurement signal at a low measured impedance and a high measured impedance.

It should be appreciated that additional filter and protection elements can be arranged between the high-pass filter 30 and the measuring electrode 12, for example in order to optimize the EMC properties of the circuit 10.

The alternating voltage excitation signal output by the signal source 14 is fed into the second signal path 22 and the third signal path 24 in parallel to the first signal path 20. In the exemplary embodiment shown, the alternating voltage excitation signal is not phase-shifted in the signal paths 22 and 24 relative to the output signal of the signal source 14.

The alternating voltage measurement signal tapped at the measuring point 32 is mixed in a first mixer-demodulator element 34, which is arranged in the second signal path 22, with the alternating voltage excitation signal fed into the second signal path 22, and the mixed signal is furthermore demodulated. Likewise, the alternating voltage measurement signal tapped at the measuring point 32 is mixed in a second mixer-demodulator element 36 with the alternating voltage excitation signal fed into the third signal path 24, and the mixed signal is demodulated. The first mixer-demodulator element 34 comprises a first mixer 38 and a first demodulator 40. The second mixer-demodulator element 36 comprises a second mixer 42 and a second demodulator 44. The first and second mixer-demodulator elements 34, 36 are preferably designed similarly to an amplitude demodulator or envelope detector. They can comprise a diode-capacitor arrangement, as shown in exemplary embodiments to be described later. If the mixer-demodulator elements 34, 36 are designed as a diode-capacitor arrangement, an inverter 46 can be arranged in one of the signal paths 22 or 24, here in signal path 24, which inverter rotates the phase of the alternating voltage excitation signal fed into the signal path 24 by 180°. Thus, the diodes in the first and second mixer-demodulator elements 34, 36 can be arranged with the same polarity to each other. If the mixer-demodulator elements 34, 36 are designed as a diode-capacitor arrangement, the respective diode has the lowest possible junction capacitance, and the respective capacitor also typically has a capacitance in the picofarad range.

The respective demodulated measurement signal output by the demodulators 40 and 44 is fed to a respective low-pass filter 48, 50, which separates the respective measurement signal from HF components. Low-pass filter 48 and low-pass filter 50 are dimensioned according to the desired step response of the circuit 10 to changes in the complex alternating current resistance to be measured. The low-pass filtered alternating voltage measurement signals are furthermore fed to a respective analog-to-digital converter 52, 54, which digitize the measurement signals. When dimensioning the low-pass filters 48, 50, the antialiasing criterion of the analog-to-digital converters 52, 54 can also be taken into account.

The digitized measurement signals are evaluated in a signal evaluation unit 56, which here can be integrated in the microcontroller 18, in order to calculate the imaginary part and real part of the alternating current resistance to be determined. Preferably, the digitized measurement signals supplied to the signal evaluation unit 56 are subtracted from one another. The measurement is carried out temporarily, for example alternately, with and without phase offset, and, according to the phase offset set on the phase shifter 26, the imaginary or real signal component of the complex alternating current resistance to be measured can be specifically determined from these measurements.

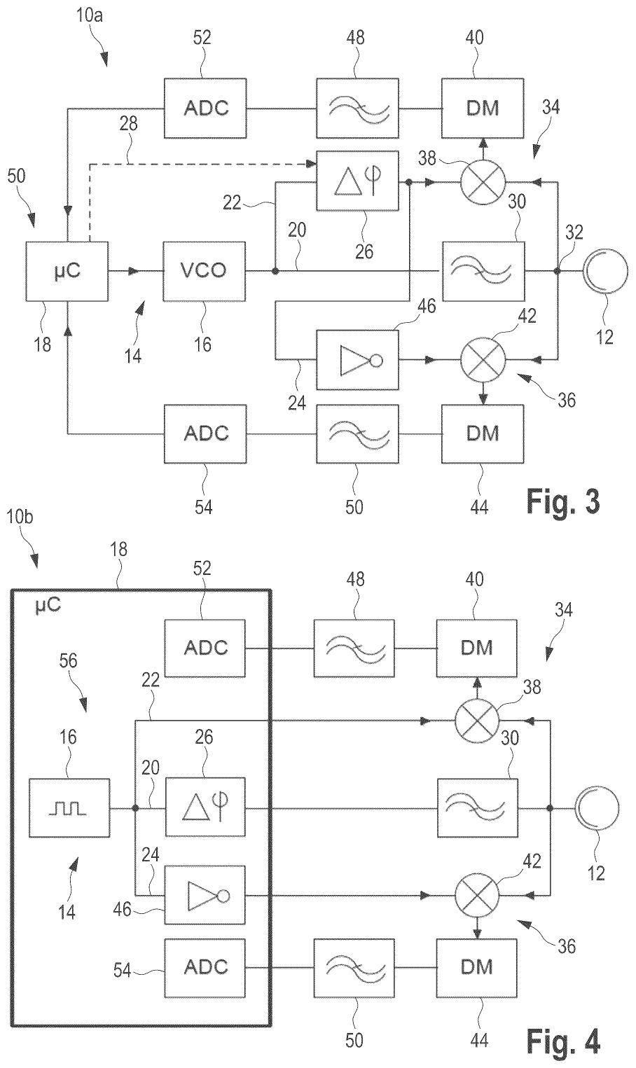

FIG. 3 shows an exemplary embodiment of a circuit 10a which is modified compared to FIG. 2. Elements of the circuit 10a that are identical or comparable to elements of circuit 10 are provided with the same reference numbers as in FIG. 2.

In the following, only the differences between circuit 10a and circuit 10 are described.

In circuit 10a, the phase shifter 26 is not arranged in the first signal path 20, but in signal paths 22 and 24. Thus, in circuit 10a, the measurement signal tapped at measuring point 32, which is not phase-shifted compared to the alternating voltage excitation signal output by signal source 14, is mixed with the phase-shifted alternating voltage excitation signals in signal paths 22 and 24 when a phase offset is set via phase shifter 26.

Thus, with circuit 10a, as with circuit 10, the real part and imaginary part of an unknown alternating current resistance Z, which is connected to the measuring electrode 12 against a reference potential, can be determined.

FIG. 4 shows another exemplary embodiment of a circuit 10b for measuring a complex alternating current resistance. Elements of circuit 10b that are identical or comparable to elements of circuit 10 in FIG. 2 are provided with the same reference numbers as in FIG. 2. In the following, only the differences between circuit 10b and circuit 10 are described.

One difference concerns the design of the signal source 14. Instead of a voltage-controlled oscillator VCO as in FIG. 2, circuit 10b has an oscillating signal generator 16 contained in the microcontroller 18 as signal source 14, which signal generator is modulated accordingly in order to output a broadband frequency spectrum. Depending on the microcontroller 18, the output alternating voltage excitation signal frequencies are in the kHz to lower MHz range. For example, the frequency spectrum output by the oscillating signal generator 16 can start at 150 kHz and extend up to a frequency of 2 MHz. The integration of the signal source 14 into the microcontroller 18 is preferred in particular for compact circuit designs, for example in the man-machine interface area in the form of buttons and the like.

Furthermore, in circuit 10b, the analog-to-digital converters 52, 54, the phase shifter 26 and the inverter 46 are also integrated in the microcontroller 18.

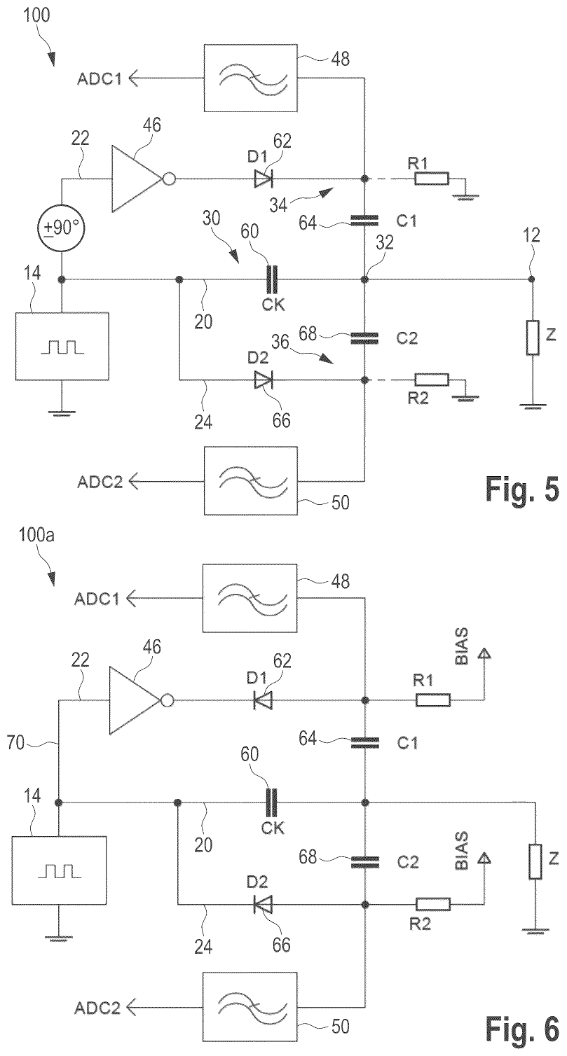

With reference to FIGS. 5 to 8, further exemplary embodiments of circuits are described which operate according to the same basic principle as circuits 10, 10a and 10b. Elements of the circuits described below that are identical or comparable to elements of circuits 10, 10a, 10b are provided with the same reference numbers as in FIGS. 2 to 4.

FIG. 5 shows a circuit 100 for measuring a complex alternating current resistance Z, which is connected to a measuring electrode 12 against the reference potential of the signal source 14. The measurement signal is tapped at a measuring point 32. The signal source 14 can be designed as described with reference to FIG. 2 or with reference to FIG. 4.

The high-pass filter 30 in FIGS. 2 to 4 is designed as a capacitor 60 in the circuit 100. The mixer-demodulator elements 34, 36 in FIGS. 2 to 4 are specifically designed here as a diode-capacitor arrangement with a diode (D1) 62 and a measuring capacitor 64, via which the diode 62 is connected to the measuring point 32, or with a diode (D2) 66, which is connected to the measuring point 32 via a measuring capacitor 68. The alternating voltage excitation signal of the signal source 14 is fed into diode 62 and into diode 66 in the second and third signal paths 22, 24 in parallel with the coupling into the first signal path 20, which contains the alternating voltage divider consisting of the capacitor 60 and the alternating current resistance Z to be measured. The inverted alternating voltage excitation signal of signal source 14 is connected to diode D1 via the inverter 46, which is arranged here in the second signal path 22. Diodes 62 and 66 are connected to the signal source 14 with the same polarity.

Diode 66 (D2) is conductive during the positive half-wave of the alternating voltage excitation signal of signal source 14, and a current flows through the measuring capacitor 68. The current through the capacitor 68 charges the latter to a measuring voltage proportional to the alternating voltage divider made up of the capacitor 60 and the alternating current resistance Z. During the negative half-wave of the alternating voltage excitation signal of signal source 14, the diode 62 is conductive due to the inverter 46. While diode 62 is conductive, a charging current flows through the measuring capacitor 64.

The voltage at measuring point 32 of measuring electrode 12 is separated from the DC voltage component of signal source 14 via capacitors 60, 64 and 68. Thus, the respective measuring voltage at the input of low-pass filters 48, 50 is equal to the charge of capacitors 64 and 68 plus an alternating voltage signal component. Low-pass filters 48, 50 separate the alternating voltage signal component from the measurement signals of the capacitor charges of capacitors 64, 68. The low-pass filtered measurement signals can then be digitized in analog-to-digital converters ADC1 and ADC2. A phase shifter, which is indicated for example by “+−90°” in FIG. 5, can be connected in the second and third signal paths 22, 24. The measurement signals digitized by the analog-to-digital converters ADC1 and ADC2 can then be evaluated in an evaluation unit as described above in order to determine the real part and the imaginary part of the complex alternating current resistance Z.

In the evaluation circuit, the difference between the digitized measurement signals is preferably formed, as described above. This not only increases the final resulting measurement signal, but also eliminates external interference signals.

Diodes 62 and 66 are preferably accommodated in a common housing to reduce temperature differences between diodes 62 and 66.

Circuit 100 in FIG. 5 has the advantage, among other things, that the resulting measurement voltages have a positive sign and can thus easily be further processed, for example, with the aid of the analog-to-digital converters ADC1.

Resistors R1 and R2 in FIG. 5 serve to divert the bias current through diodes 62 and 66 against a reference potential. The reference potential can be a reference voltage source or, as shown in FIG. 5, the reference potential of signal source 14. The resistors R1 and R2 also reduce or prevent signal drift due to the bias currents.

FIG. 6 shows a circuit 100a, which is a variant of the circuit 100 in FIG. 5. Elements of circuit 100a that are identical or comparable to elements of circuit 100 in FIG. 5 are provided with the same reference numbers as in FIG. 5. Hereinafter, only differences to circuit 100 will be described.

In circuit 100a and circuit 100, the two diodes 62, 66 are connected to signal source 14 with opposite polarity compared to FIG. 5, but with same polarity among each other. A bias voltage (BIAS) may be additionally required. The bias voltage ensures that diodes 62 and 66 are put into a conductive state when the voltage level at the cathode of the respective diode is sufficiently below the bias voltage. The current through diodes 62 and 66 is additionally limited by a respective resistor R1 and R2.

The capacitors 64, 68 of circuits 100 and 100a can be dimensioned to be substantially the same size with regard to their capacitances. But they can also have different dimensions.

The resistors R1, R2 or input resistances of low-pass filters 48, 50 can be many times greater than the alternating current resistance of the capacitor 66 of the high-pass filter 30 over the frequency range of signal source 14.

Diodes 62 and 66 should have as small a junction capacitance as possible.

In FIG. 6, a phase shifter can be provided at a position 70.

In order to determine the complex alternating current resistance Z, a phase-shifted measurement signal is required in addition to measuring the measuring voltage at measuring point 32 in phase with the alternating voltage excitation signal of signal source 14. For this purpose, as shown in FIG. 5, the alternating voltage excitation signal is coupled into signal paths 22, 24, for example offset by 90°. The measurement with and without phase offset can be carried out alternately by switching the phase offset on or off. The measuring voltage at measuring point 32 can be determined for a certain period of time, e.g., the period of time required to pass through a certain frequency spectrum (wobble period). The measurement is then repeated with a phase offset of, for example, +or −90°. The two measurement signals obtained in this way can be used as measured variables for the complex alternating current resistance for amplitude and phase calculation of the alternating current resistance Z.

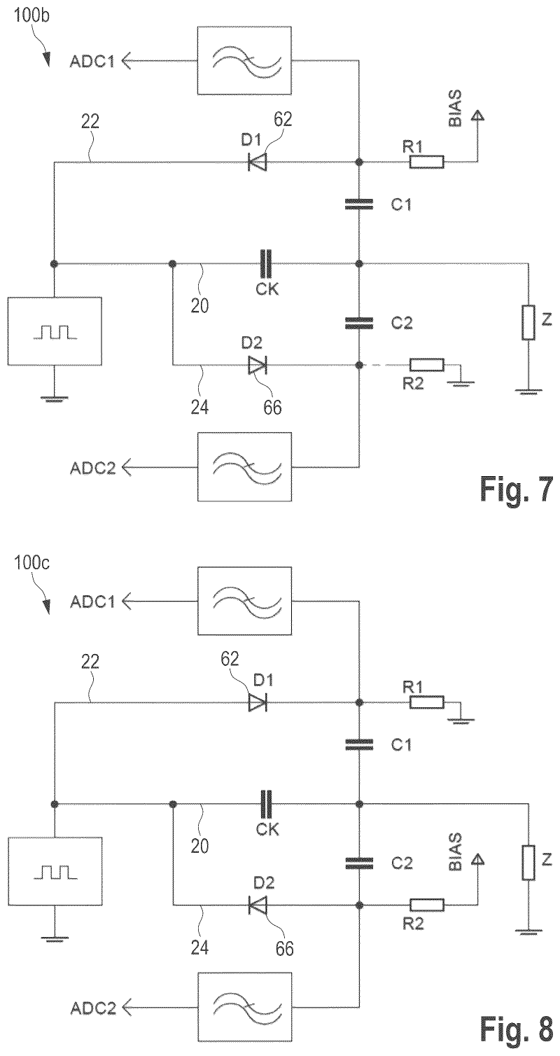

FIGS. 7 and 8 show further exemplary embodiments of a circuit 100b and circuit 100c, wherein for elements that are identical or comparable to elements of circuit 100 in FIG. 5, the same reference numbers as in FIG. 5 were used again. Only differences to circuit 100 are described.

In FIG. 7, diodes 62 and 66 are arranged with opposite polarity to each other in the second and third signal paths 22, 24, respectively. The inverter 46 can therefore be omitted.

The same applies to circuit 100c in FIG. 8, in which the two diodes 62, 66 are arranged in the corresponding signal paths 22 and 24 with reverse polarity with respect to FIG. 7.

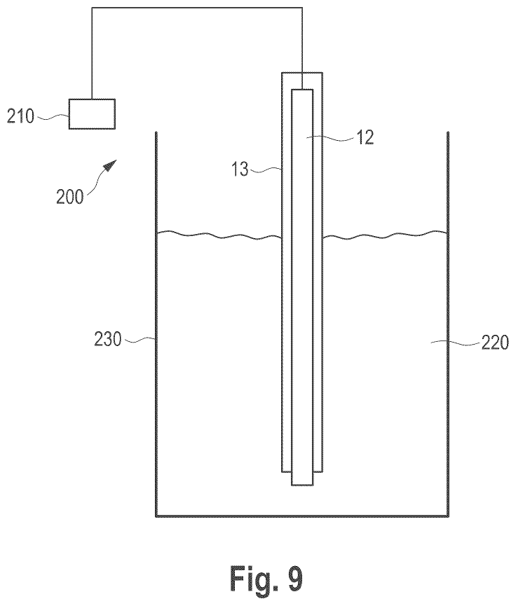

FIG. 9 shows an impedance sensor 200 having the measuring electrode 12 and a circuit 210 connected to the measuring electrode 12. Circuit 210 can be circuit 10, 10a, 10b, 100, 100a, 100b, 100c.

In the exemplary embodiment in FIG. 9, the impedance sensor 200 is used as a fill level sensor to continuously monitor the fill level of a liquid medium 220 or a bulk material 220 in a tank 230. For this purpose, the measuring electrode 12 can be designed as a rod. A conductive sheath tube 13 or the wall of tank 230 can serve as a counter electrode, provided that the wall of tank 230 is at least partially conductive. Measuring electrode 12 and the counter electrode form a capacitor. The value of the capacitor is continuously changed by the fill level in tank 230 and can be measured by circuit 210. Conductive contaminants, such as biofilms or other deposits in tank 230, can be detected via the real part, i.e., the conductive component of the measured alternating current resistance via the sensor electronics of circuit 210. However, changes in the media properties, which are reflected in the conductivity of medium 220, can also be detected via the conductive measurement value.

Another application of an impedance sensor designed with or connected to a circuit 10, 10a, 10b, 100, 100a, 100b, 100c can be the design as a limit level switch. Measuring electrode 12 can be designed as a cap, for example. If the cap of the limit level switch is contacted by a process medium, the measured capacitance changes significantly and switching activity can be triggered. This makes it possible to implement dry-run protection for pumps or overflow protection when filling open containers. Here, too, the conductive measurement value can be used to detect contamination or changes in the process medium.

Another possible use of an impedance sensor with a circuit according to the present exemplary embodiments is the use as a proximity sensor in the automation industry. Similar to a limit level switch, a switching application is triggered as a function of the value of the measured alternating current resistance. As soon as an object comes closer to measuring electrode 12, the capacitance between measuring electrode 12 and ground potential changes. A switching activity can be triggered if the signal change due to this capacitance is sufficiently large. The conductive measurement can be used to distinguish between objects. However, it can also be used to detect conductive deposits on measuring electrode 12 of the proximity sensor. This makes it possible to continue to detect objects in processes in which, for example, water films or puddles form on the proximity sensor.

Further uses of an impedance sensor with a circuit according to any one of the exemplary embodiments described above are in the field of man-machine interaction in the form of buttons, slide or rotary encoders. Furthermore, applications as flow monitors are possible, in which the properties of the process medium are monitored in relation to capacitive or conductive coupling to the impedance sensor.

What is claimed is:

1. A circuit for measuring a complex alternating current resistance, comprising:
a signal source configured to generate an alternating voltage excitation signal,
a first signal path, a second signal path and a third signal path, into each of which the alternating voltage excitation signal of the signal source is fed in parallel to one another;
wherein the alternating voltage excitation signal is fed into the first signal path or into the second and third signal path at least temporarily with a phase offset compared to the alternating voltage excitation signal generated by the signal source;
wherein the first signal path comprises a high-pass filter and, in series therewith, the alternating current resistance to be measured;
wherein a measurement signal tapped at a measuring point between the high-pass filter and the alternating current resistance to be measured is mixed with the alternating voltage excitation signal in the second signal path and is furthermore demodulated in order to obtain a first demodulated measurement signal, and is mixed with the alternating voltage excitation signal in the third signal path and furthermore demodulated in order to obtain a second demodulated measurement signal; and
a signal evaluation unit that receives the demodulated measurement signals and determines from the demodulated measurement signals the imaginary part and real part of the alternating current resistance to be measured.

2. The circuit according to claim 1, wherein the second signal path comprises a first diode and a first measuring capacitor, wherein the measuring capacitor is connected to the measuring point between the high-pass filter and the alternating current resistance to be measured, and the third signal path comprises a second diode and a second measuring capacitor, wherein the second measuring capacitor is connected to the measuring point between the high-pass filter and the alternating current resistance to be measured, wherein the first and the second diode are arranged to alternately pass a half-wave of the alternating voltage excitation signal.

3. The circuit according to claim 2, wherein at least one of the first measuring capacitor or the second measuring capacitor has a capacitance in the picofarad range.

4. The circuit according to claim 2, wherein an inverter is arranged in the second or in the third signal path, which inverter is connected to the signal source and is connected upstream of the first diode or the second diode, and which inverts the alternating voltage excitation signal coming from the signal source.

5. The circuit according to claim 1, wherein the high-pass filter comprises a capacitor.

6. The circuit according to claim 1, wherein a frequency spectrum of the alternating voltage excitation signal generated by the signal source comprises frequencies in a range of 100 kHz to 200 MHz.

7. The circuit according to claim 1, wherein the signal source is configured to generate the alternating voltage excitation signal with a variable frequency.

8. The circuit according to claim 1, wherein the phase offset is an odd integer multiple of 90°.

9. The circuit according to claim 1, further comprising a first low-pass filter and a second low-pass filter into which the demodulated measurement signals are fed.

10. The circuit according to claim 1, further comprising at least one of a first analog-to-digital converter or a second analog-to-digital converter for digitizing the demodulated measurement signals.

11. The circuit according to claim 1, wherein the signal evaluation unit subtracts the demodulated measurement signals from one another.

12. An impedance sensor, comprising
a measuring electrode, wherein a complex alternating current resistance to be measured is connected to the measuring electrode against a reference potential; and
a circuit for measuring a complex alternating current resistance according to claim 1.

13. Method of using the impedance sensor according to claim 12 for at least one of detecting a fill level of a medium in a container, detecting changes in properties of a medium, distinguishably detecting different media or objects.

14. Method of using the impedance sensor according to claim 12 as at least one of a proximity sensor, a button, a slide or rotary encoder.
